(19) United States
(12) Patent Application Publication
(10) Pub. No.: US 2004/0070938 A1
(43) Pub. Date: Apr. 15, 2004

(54) Circulating system for a conductor

(76) Inventors: Andrew J. Hazelton, San Carlos, CA (US); Kazuya Ono, San Carlos, CA (US)

Correspondence Address: Steven G. Roeder, THE LAW OFFICES OF STEVEN G. ROEDER, 5560 Chelsea Avenue, La Jolla, CA, 92037, US

(21) Appl. No.: 09/754,856

(22) Filed: Jan. 4, 2001

(51) Int. Cl. H05K 7/20

(52) U.S. Cl. 361/688

(57) ABSTRACT

A circulating system (10) for circulating a fluid (24) from a fluid source (28) around an attraction only type actuator (12) is provided herein. The actuator (12) includes a first core (18), a second core (22), and a tubular conductor (20). The circulating system (10) includes a circulation housing (26) and a fluid inlet (60). The circulation housing (26) is sized and shaped to encircle the conductor (20) and provide a fluid passageway (44) between the circulation housing (26) and the conductor (20). The fluid inlet (60) extends into the fluid passageway (44) and is in fluid communication with the fluid source (28). Fluid (24) from the fluid source (28) is directed through the fluid inlet (60) into the fluid passageway (44). Preferably, the flow rate of the fluid (24) is controlled to maintain an outer surface (96) of the circulation housing (26) at a set temperature to control the influence of the actuator (12) on the surrounding environment and the surrounding components.

### FIELD OF THE INVENTION

The present invention relates to a circulating system for a conductor. The invention is particularly useful for maintaining an outer surface of an attraction only actuator at a set temperature to control the influence of the actuator on the surrounding environment and the surrounding components.

### BACKGROUND

Actuators are used in a variety of electrical devices. For example, actuators are used in exposure apparatuses for semiconductor processing, other semiconductor processing equipment, machine tools, machines, and inspection machines.

Exposure apparatuses for semiconductor processing are commonly used to transfer images from a reticle onto a semiconductor wafer. Typically, the exposure apparatus utilizes one or more actuators to precisely position a wafer stage holding the semiconductor wafer relative to the reticle. The images transferred onto the wafer from the reticle are extremely small. Accordingly, the precise positioning of the wafer and the reticle is critical to the manufacturing of the wafer. In order to obtain precise relative alignment, the position of the reticle and the wafer are constantly monitored by a measurement system. Subsequently, with the information from the measurement system, the reticle and/or wafer are moved by the one or more actuators to obtain relative alignment.

One type of actuator is an attraction only type electromagnetic actuator commonly referred to as an E/I core actuator. Typically, E/I core actuators consume less power and generate less heat than a voice coil motor or a linear motor. Each E/I core actuator includes a target and a pair of spaced apart electromagnets positioned on each side of the target. Each electromagnet includes an E shaped core and a tubular conductor. The target includes one or more I shaped cores.

Current directed through the conductor creates an electromagnetic field that attracts the I core towards the E core. The amount of current determines the amount of attraction. Stated another way, when the conductor of an electromagnet is energized, the electromagnet generates a flux that produces an attractive force on the target. Because the electromagnets can only attract the targets, they must be assembled in pairs that can pull in opposition. By making a current through one conductor of the pair of electromagnets larger than the current through the other conductor in the pair, a differential force can be produced that draws the target in one direction or its opposing direction.

Unfortunately, the electrical current supplied to the conductors of the E/I core actuator also generate heat, due to resistance in the conductors. Most actuators are not actively cooled. Thus, the heat from the conductors is subsequently transferred to the surrounding environment, including the air surrounding the actuator and the other components positioned near the actuator. The heat changes the index of refraction of the surrounding air. This reduces the accuracy of the measurement system and degrades machine positioning accuracy. Further, the heat causes expansion of the other components of the machine. This further degrades the accuracy of the machine. Moreover, the resistance of the conductors increases as temperature increases. This exacerbates the heating problem and reduces the performance and life of the actuator.

In light of the above, there is a need for maintaining an outer surface of an attraction only type actuator at a set temperature during operation. Additionally, there is a need for a system for cooling a tubular shaped conductor. Moreover, there is a need for an exposure apparatus capable of manufacturing precision devices such as high density semiconductor wafers.

### SUMMARY

The present invention is directed to a circulating system for circulating a fluid from a fluid source around a portion of a tubular conductor. The conductor is typically used as part of an actuator that also includes a first core and a second core. The circulating system includes a circulation housing and a fluid inlet. The circulation housing is sized and shaped to substantially encircle the conductor and provide a fluid passageway between the circulation housing and the conductor. The fluid inlet extends into the fluid passageway and is in fluid communication with the fluid source. Fluid from the fluid source is directed or forced through the fluid inlet into the fluid passageway.

Typically, the actuator is used as an attraction only type actuator. As used herein, the term “attraction only type actuator” shall mean “an actuator that includes a target and a pair of electromagnets positioned on opposite sides of the target. The electromagnets can only attract the target and the electromagnets pull in opposition.”

Preferably, the rate of flow of the fluid to the fluid passageway is controlled to maintain an outer surface of the circulation housing at a predetermined temperature. By controlling the outer surface temperature of the circulation housing, heat transferred from the conductor to the surrounding environment can be controlled and/or eliminated. This minimizes the influence of the conductor on the surrounding environment.

As provided herein, the circulating system can include a fluid guide that extends between the circulation housing and the conductor. Preferably, the fluid guide supports the conductor spaced apart from the circulation housing and guides the flow of the fluid in the fluid passageway so that the fluid flows around the conductor. With this design, the fluid guide minimizes direct thermal contact between the circulation housing and the conductor and minimizes the heat transfer from the conductor to the circulation housing. Additionally, the fluid guide enhances the flow of the fluid in the fluid passageway.

Preferably, the fluid guide includes a first rail and a second rail that are positioned in the fluid passageway. In this embodiment, the rails cooperate to direct the flow of fluid in the fluid passageway over an outer perimeter, a top surface, a bottom surface and an inner perimeter of the conductor.

The circulation housing includes a housing outer shell that encircles the conductor and a housing inner shell that fits within and is encircled by the conductor. The housing outer shell and the housing inner shell can be substantially coaxial.

Additionally, the present invention includes an outlet that is in fluid communication with the fluid passageway. The outlet allows the fluid to be transferred from the fluid passageway back to the fluid source.

The present invention is also directed to (i) an actuator combination including a first core, a second core, a conductor, and the circulating system, (ii) a stage assembly including the actuator combination, (iii) an exposure apparatus including the actuator combination, and (iv) an object on which an image has been formed by the exposure apparatus. Further, the present invention is also directed to a method for making a circulating system, a method for making an actuator combination, a method for making a stage assembly, a method for manufacturing an exposure apparatus and a method for manufacturing an object or a wafer.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a side plan view of an actuator combination having features of the present invention;

FIG. 2 is a perspective view of a portion of the actuator combination of FIG. 1;

FIG. 3A is a perspective view of a circulation housing having features of the present invention;

FIG. 3B is a partly exploded perspective view of the circulation housing of FIG. 3A;

FIG. 3C is an exploded perspective view of the circulation housing, a flow guide and a conductor having features of the present invention;

FIGS. 4A-4C are alternate perspective views of the conductor and the flow guide that illustrate the flow of a circulating fluid about the conductor;

FIG. 5 is a perspective view of a stage assembly having features of the present invention;

FIG. 6 is an exploded perspective view of a portion of the stage assembly of FIG. 5;

FIG. 7 is a schematic illustration of an exposure apparatus having features of the present invention;

FIG. 8 is a flow chart that outlines a process for manufacturing a device in accordance with the present invention; and

FIG. 9 is a flow chart that outlines device processing in more detail.

### DESCRIPTION

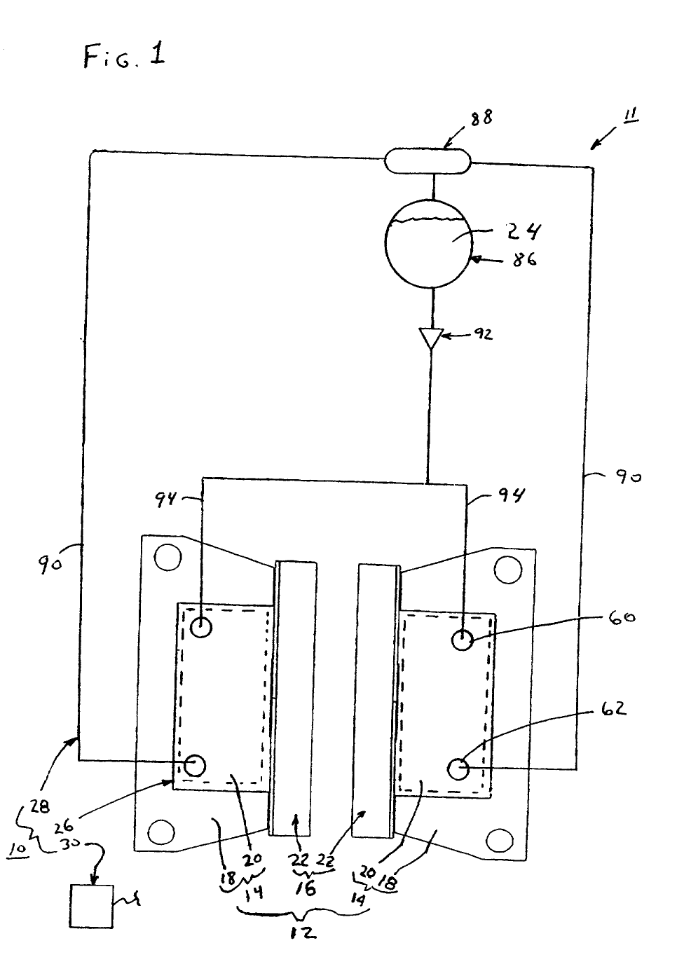

Referring initially to FIG. 1, the present invention is directed to a circulating system 10 and an actuator combination 11 that includes the circulating system 10 and an actuator 12. The actuator 12 illustrated in FIG. 1 is an attraction only type, commonly referred to as an E/I core actuator. The actuator 12 includes a pair of spaced apart electromagnets 14 and a target 16 positioned between the electromagnets 14. In the embodiment illustrated in FIG. 1, each of the electromagnets 14 includes a first core 18 and a tubular conductor 20 (illustrated in phantom in FIG. 1) and the target 16 includes a pair of second cores 22.

Uniquely, the circulating system 10 directs a circulating fluid 24 around each conductor 20 to cool each conductor 20. With this design, for an actuator combination 11, the circulating system 10 can be used to cool the conductor 20 of each of the electromagnets 14 and inhibit the transfer of heat from each conductor 20 to the environment that surrounds the actuator 12. Stated another way, the circulating system 10 can be used to maintain the temperature of the actuator 12. This minimizes the influence of the actuator 12 on the surrounding environment and allows for more accurate positioning by the actuator 12. As an overview, in the embodiment illustrated in the Figures, the circulating system 10 includes a circulation housing 26 for each conductor 20, a fluid source 28 of the fluid 24 and a control system 30 for controlling the fluid source 28.

The size and shape of the actuator 12 can be varied to suit the movement requirements of the actuator 12. In the embodiment illustrated in the Figures, the first core 18 is substantially E shaped while the second core 22 is substantially I shaped. Alternately other shapes for the cores 18, 22 are possible. For example, the cores 18, 22 can be the shape of the cores in any electromagnetic type actuator. The first core 18 and the second core 22 are each made of a magnetic material such as iron, silicon steel, or Ni—Fe steel.

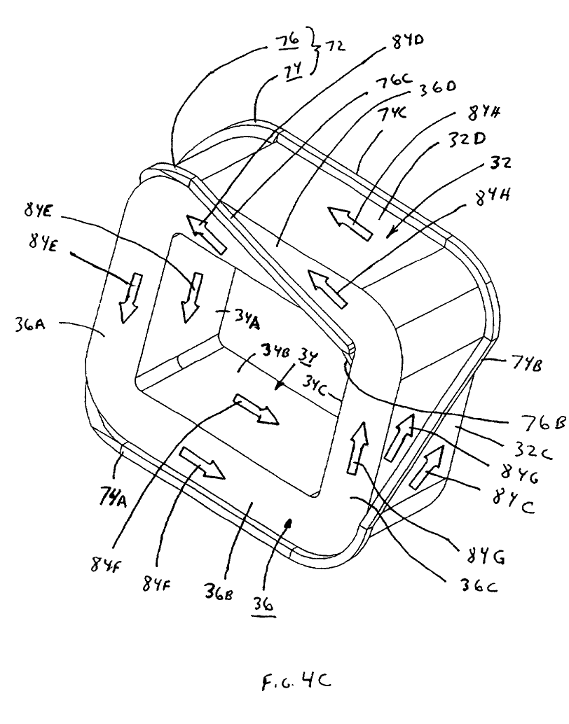

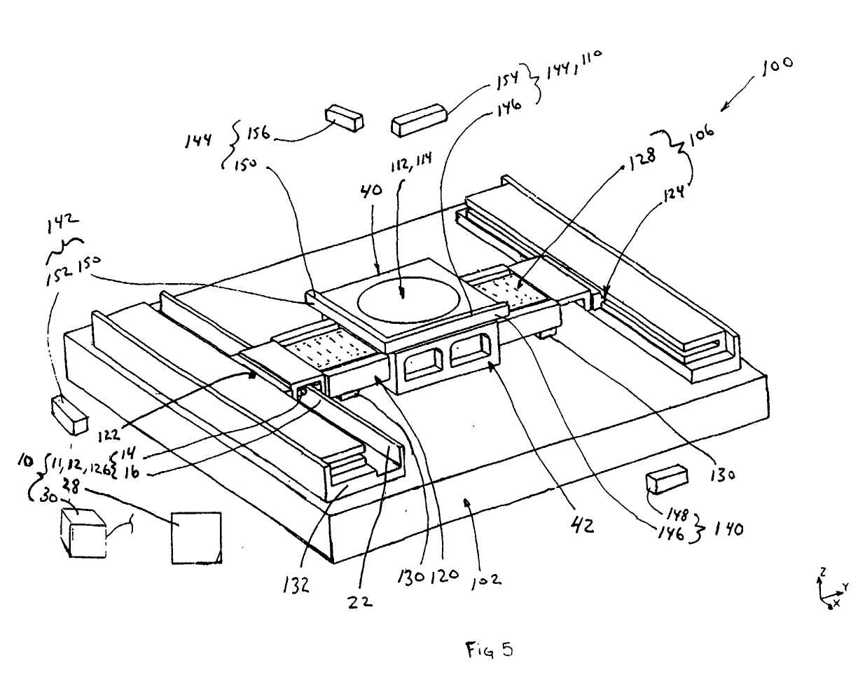

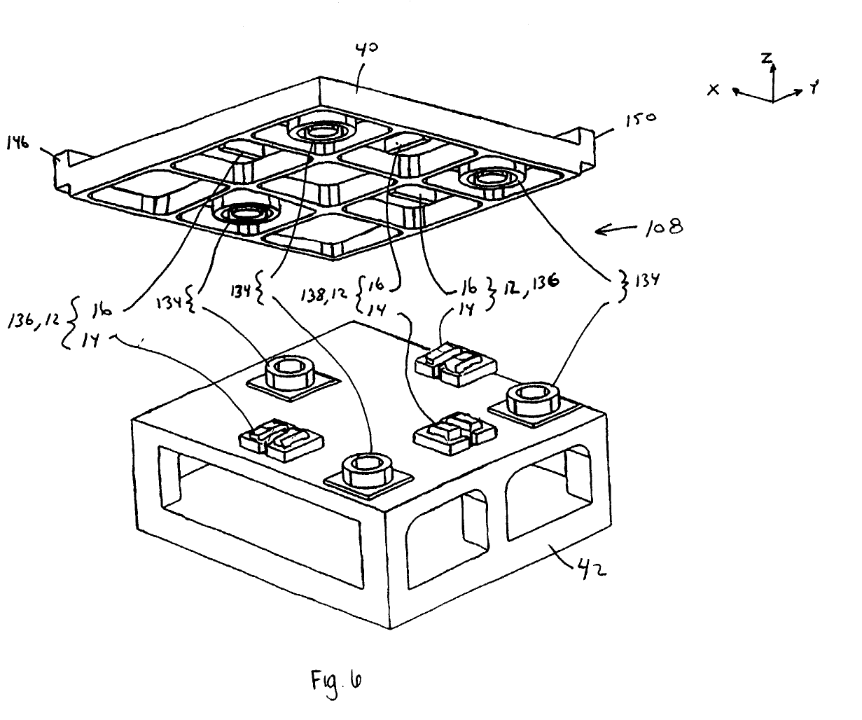

The conductor 20 is positioned around a portion of the first core 18. In the embodiment illustrated in the Figures, the conductor 20 is positioned around the center bar of the E shaped first core 18 between the upper bar and the lower bar of the E shaped core. Referring to FIGS. 4A-4C, the conductor 20 is generally annular and/or rectangular tube shaped. The conductor 20 includes (i) an outer perimeter 32, (ii) an inner perimeter 34, (iii) a top surface 36, and (iv) a bottom surface 38. The outer perimeter 32 includes an outer front side 32A, an outer right side 32B, an outer back side 32C and an outer left side 32D. The inner perimeter 34 includes an inner front side 34A, an inner right side 34B, an inner back side 34C and an inner left side 34D. The top surface 36 includes a top front side 36A, a top right side 36B, a top back side 36C and a top left side 36D. The bottom surface 38 includes a bottom front side 38A, a bottom right side 38B, a bottom back side 38C and a bottom left side 38D.

It should be noted that the use of the terms top, bottom, front, back, left and right is in reference to orientation of the conductor 20 illustrated in FIG. 4A and is for the convenience of the reader. It should be understood that these terms are merely for reference and can be varied. For example, the front side can be switched with the back side and/or the orientation of the conductor 20 can be rotated.

The conductor 20 is made of metal such as copper or any substance or material responsive to electrical current and capable of creating a magnetic field. The conductor 20 is typically made of electrical wire encapsulated in an epoxy. The conductor 20 is illustrated in the Figures and described in detail as part of an actuator combination 11. Alternately, for example, the conductor 20 to be cooled can be used as part of a transformer or a shaft type linear motor.

In use, each electromagnet 14 and target 16 is separated by an air gap g (not shown). The electromagnets 14 are variable reluctance actuating portions and the reluctance varies with the distance defined by the gap g, which also varies the flux and force applied to the target 16. The attractive force between the electromagnet 14 and the target 16 is defined by:

F=K(i/g)²

Where F is the attractive force, measured in Newtons;

K is an electromagnetic constant that is dependent upon the geometries of the first core 18, the second core 22, and the number of coil turns in the conductor 20. K=1/2N²μₒwd; where N=the number of turns of the conductor 20 about the first core 18; μₒ=a physical constant of about 1.26×10⁻⁶H/m; w=the half width of the center of the First core 18 in meters; and d=the depth of the center of the First core 18 in meters. In a preferred embodiment, K=7.73×10⁻⁶ kg m³/s²A²; i=current, measured in amperes; and g=the gap distance, measured in meters.

Current (not shown) directed through the conductor 20 creates an electromagnetic field that attracts the second core 22 towards the First core 18. The amount of current determines the amount of attraction. Stated another way, when the conductor 20 of the electromagnet 14 is energized, the electromagnet 14 generates a flux that produces an attractive force on the target 16 in accordance with the formula given above, thereby functioning as an actuating portion. Because the electromagnets 14 can only attract the target 16, they must be assembled in pairs that can pull in opposition.

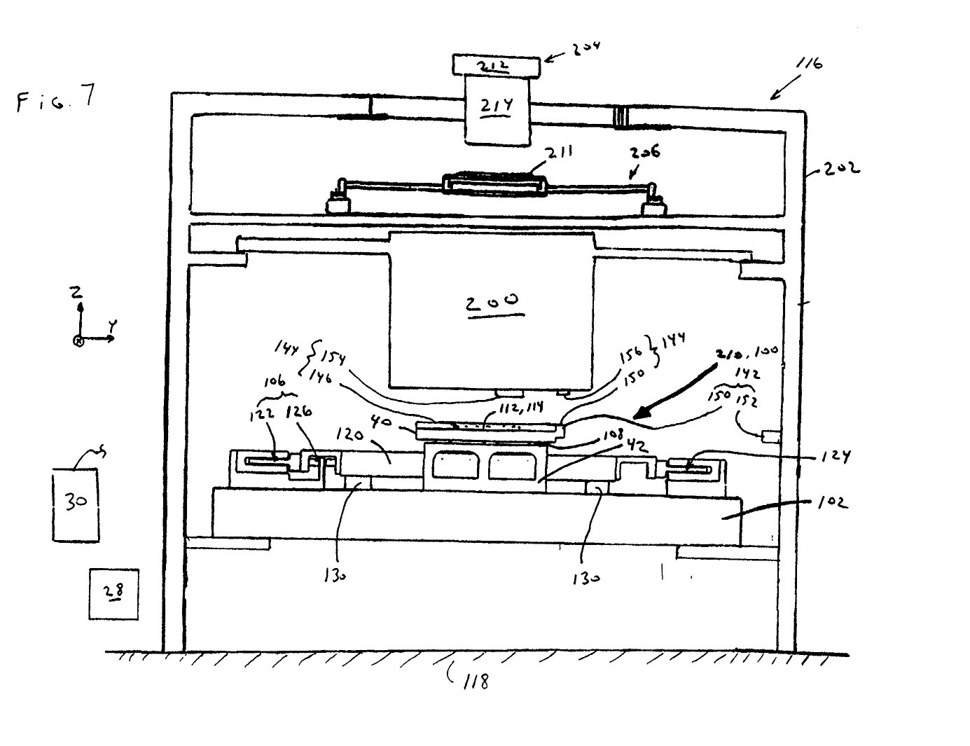

As illustrated in FIG. 6 and discussed below, a plurality of targets 16 can be fixed to a device stage 40. Opposing pairs of the electromagnets 14 are secured to a mover housing 42 on opposite sides of each of the targets 16. By directing a current through the one conductor (not shown in FIG. 6) of the pair of electromagnets 14 larger than the current through the other conductor (not shown in FIG. 6) in the pair of electromagnets 14, a differential force can be produced that draws the target 16 in one direction or its opposing direction.

The circulating system 10 preferably maintains the temperature of the actuator 12 and inhibits the actuator 12 from transferring heat to the environment that surrounds the actuator 12. As provided above, in the embodiment illustrated in the Figures, the circulating system 10 includes the circulation housing 26, the fluid source 28 and the control system 30. Preferably, the circulation system 10 also supports the conductor 20 spaced apart from the center bar of the First core 18 to reduce heat transfer between the conductor 20 and the First core 18.

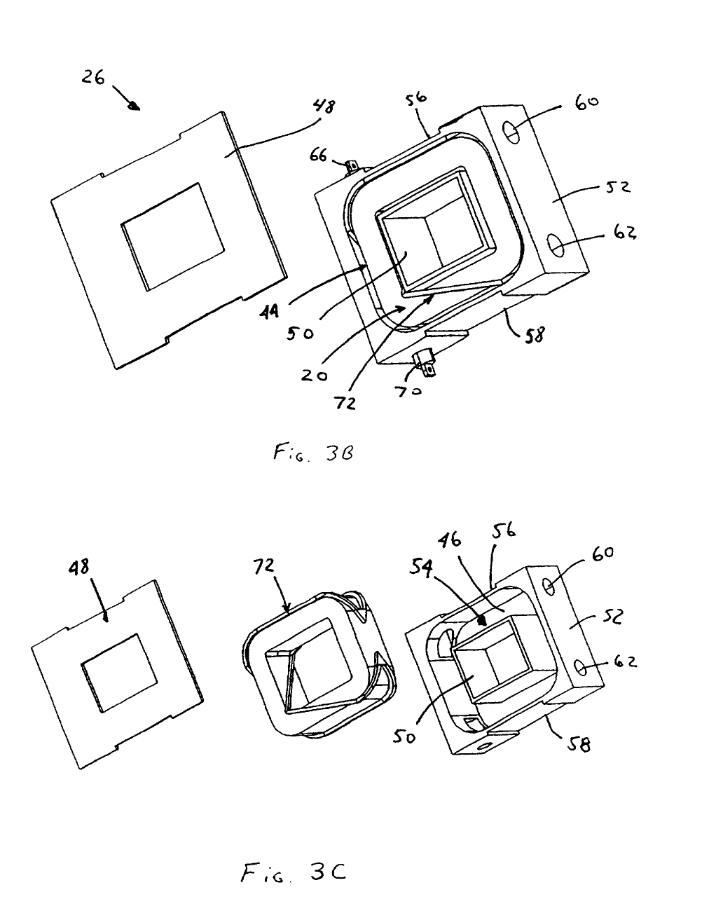

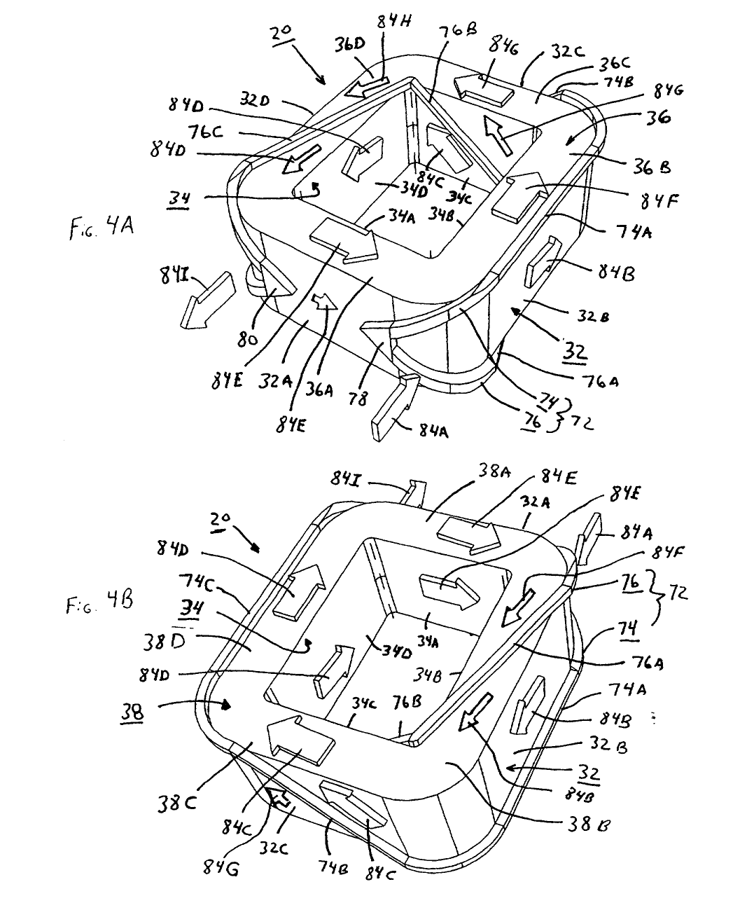

The circulation housing 26 surrounds the conductor 20 and provides a fluid passageway 44 (illustrated in FIG. 3B) between the circulation housing 26 and the conductor 20. Preferably, the fluid passageway 44 encircles substantially the entire conductor 20 so that the fluid 24 passes over and contacts substantially the entire conductor 20.

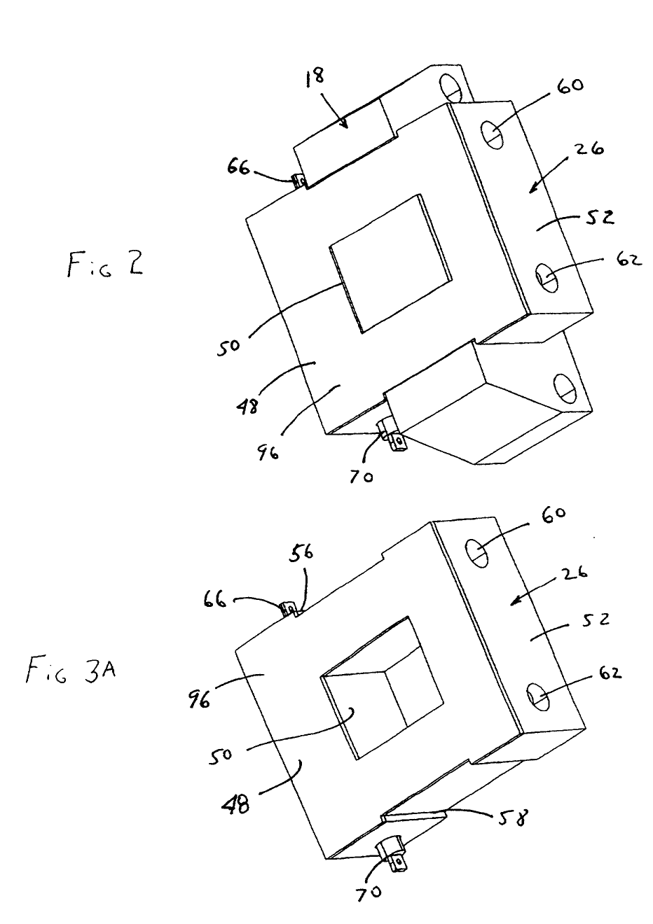

The design of the circulation housing 26 is varied according to the design of the conductor 20. Referring to FIGS. 2, 3A-3C, in the embodiments illustrated in the Figures, the circulation housing 26 includes a housing back 46, a housing front 48, a housing inner shell 50 and a housing outer shell 52 that cooperate to form a housing cavity 54 that receives the conductor 20. The conductor 20 is positioned (i) between the housing back 46 and the housing front 48 and (ii) between the housing inner shell 50 and the housing outer shell 52.

The housing cavity 54 illustrated in the Figures is generally rectangular tube shaped for receiving the rectangular tube shaped conductor 20. The circulation housing 26 also includes (i) an upper notch 56 that receives a portion of the upper bar of the First core 18 and (ii) a lower notch 58 that receives a portion of the lower bar of the First core 18.

The housing back 46 and the housing front 48 are generally parallel and spaced apart. The housing back 46 and the housing front 48 are each shaped somewhat like a flat, rectangular shaped ring. The housing inner shell 50 is generally rectangular tube shaped and is sized and shaped to fit within the conductor 20. The housing outer shell 52 is generally rectangular tube shaped and is sized and shaped to encircle the conductor 20. The housing inner shell 50 is positioned within as is generally coaxial and concentric with the housing outer shell 52.

For structural rigidity, the housing back 46, the housing inner shell 50, and the housing outer shell 52 are preferably formed as a single component. In this embodiment, the housing front 48 is removable from the rest of the circulation housing 26 as illustrated in FIGS. 3B and 3C to allow access to the conductor 20 and the housing cavity 54. Preferably, the housing front 34 is sealed to the rest of the circulation housing 26 with a weld or an epoxy. Alternately, for example, the housing front 34 can be sealed to the rest of the circulation housing 26 with an O-ring (not shown) and bolts (not shown).

The circulation housing 26 is preferably made of a low or non-electrically conductive, non-magnetic material, such as low electrical conductivity stainless steel or titanium, or non-electrically conductive plastic or ceramic.

The circulation housing 26 includes (i) a fluid inlet 60 that allows for the flow of fluid 24 from the fluid source 28 into the fluid passageway 44 and (ii) a fluid outlet 62 that allows for the flow of fluid 24 from the fluid passageway 44 to the fluid source 28. The location of the fluid inlet 60 and fluid outlet 62 can be varied to influence the cooling of the actuator 12. In the embodiment illustrated in Figures, (i) the fluid inlet 60 is an aperture in the housing outer shell 52 of the circulation housing 26 that extends into the fluid passageway 44 and (ii) the fluid outlet 62 is an aperture in the housing outer shell 52 of the circulation housing 26 that extends into the fluid passageway 44.

Alternately, the single fluid inlet 60 and the single fluid outlet 62, illustrated in the Figures, can be replaced by a pair of fluid inlets and a pair of fluid outlets. This allows for the use of smaller lines or hoses from the fluid source 28 to the circulation housing 26. The smaller lines or hoses flex more easily than the larger lines and hoses.

Additionally, the circulation housing 26 includes (i) an electrical power in connector 66 that extends through the housing outer shell 52 and connects to the conductor 20 and (ii) an electrical power out connector 70 that extends through the housing outer shell 52 and connects to the conductor 20. The power in connector 66 and power out connector 70 allow for current to be directed to the conductor 20.

Preferably, the circulating system 10 includes a fluid guide 72 that (i) supports the conductor 20 spaced apart from the circulation housing 26 in the housing cavity 54 and (ii) directs the fluid 24 to circulate around substantially the entire exposed surface area of the conductor 20. The distance in which the fluid guide 72 maintains the conductor 20 spaced apart from the circulation housing 26 is preferably between approximately 0.1 mm and 5 mm. Importantly, the fluid guide 72 provides the fluid passageway 44 between the conductor 20 and the circulation housing 26 and allows for flow of the fluid 24 to circulate around substantially the entire exposed surface area of the conductor 20. Alternately, the fluid guide can be attached to the circulation housing.

The design of the fluid guide 72 can be varied to suit the design requirements of the actuator 12. In the embodiments illustrated in FIGS. 4A-4C, the fluid guide 72 includes a first rail 74 and a second rail 76 that cooperate to support the conductor 20 spaced apart from the circulation housing 26 and to direct the fluid 24 around all of the sides 32A-32D, 34A-34D, 36A-36D, 38A-38D of the conductor 20. In the embodiment illustrated in FIGS. 4A-4C, each of the rails 74, 76 have a somewhat rectangular shaped cross-section. Further, each of the rails 74, 76 is wrapped around the conductor 20.

Referring to FIGS. 4A-4C, the first rail 74 and the second rail 76 are initially together and diverge apart to form a right “V” 78 near the right edge of the outer front side 32A. Next, (i) the first rail 74 includes a right first rail section 74A that extends along the upper edge of the outer right side 32B and (ii) the second rail 76 includes a right second rail section 76A that extends from the lower edge of the outer right side 32B diagonally across the bottom right side 38B to the lower edge of the inner right side 34B. Subsequently, (i) the first rail 74 includes a rear first rail section 74B that extends from near the upper edge of the outer back side 32C diagonally across the outer back side 32C to the lower edge of the outer back side 32C and (ii) the second rail 76 includes a rear second rail section 76B that extends from near the lower edge of inner back side 34C diagonally across to the inner back side 34C to near the upper edge of the inner back side 34C. Next, (i) the first rail 74 includes a left first rail section 74C that extends along the lower edge of the outer left side 32D and (ii) the second rail 76 includes a left second rail section 76C that extends diagonally across the top left side 36D from near the inner back side 34C to near the outer left side 32D. Subsequently, the first rail 74 and the second rail 76 converge together to form a left “V” 80 near the left edge of the outer front side 32A.

With this design, the rails 74, 76 cooperate to direct the fluid 24 to pass over and contact substantially the entire conductor 20. Stated another way, the rails cooperate to direct fluid 24 around each of the sides 32A-32D, 34A-34D, 36A-36D, 38A-38D of the conductor 20.

Each of the rails 74, 76 is preferably made of a low or non-electrically conductive, non-magnetic material, such as low electrical conductivity epoxy, stainless steel or titanium, or non-electrically conductive plastic or ceramic. One or both rails 74, 76 can be secured directly to the circulation housing 26 around the housing cavity 54. Alternately, for example, one or both rails 74, 76 can be secured directly to the conductor 20.

FIGS. 4A-4C also include a plurality of arrows 84A-84I to illustrate how the rails 74, 76 direct the flow of fluid (not shown in FIGS. 4A-4C) around each of the sides 32A-32D, 34A-34D, 36A-36D, 38A-38D of the conductor 20. More specifically, arrow 84A illustrates that the fluid enters into the fluid passageway within the right “V” 78 near the right edge of the outer front side 32A. Next, arrows 84B illustrate that the fluid flows along the outer entire right side 32B and along a portion of the bottom right side 38B. Subsequently, arrows 84C illustrate that the fluid flows along a portion of the outer back side 32C, along the entire bottom back side 38C and along a portion of the inner back side 34C. Next, arrows 84D illustrate that the fluid flows along a portion of the top left side 36D, along the entire inner left side 34D, and along the entire bottom left side 38D. Subsequently, arrows 84E illustrate that the fluid flows along the entire inner front side 34A, along the entire top front side 36A, along the entire bottom front side 38A and along a portion of the outer front side 32A between the left “V” 80 and the right “V” 78. Next, arrows 84F illustrate that the fluid flows along a portion of the bottom right side 38B, along the entire inner right side 34B and along the entire top right side 36B. Subsequently, arrows 84G illustrate that the fluid flows along a portion of the inner back side 34C, along the entire top back side 36C and along a portion of the outer back side 32C. Next, arrows 84H illustrate that the fluid flows along a portion of the top left side 36D and along the entire outer left side 32D. Finally, arrow 841 illustrates that the fluid exits the fluid passageway within the left “V” 80 near the left edge of the outer front side 32A.

With this design, the fluid 24 entering the fluid passageway 44 is directed around each of the sides 32A-32D, 34A-34D, 36A-36D, 38A-38D of the conductor 20. This reduces the likelihood of localized hot areas. Further, with the fluid 24 swirling in the fluid passageway 44, the distance traveled by the fluid 24 is increased in the fluid passageway 44. This increases the thermal transfer from the conductor 20 to the fluid 24.

It should be noted that the rails 74, 76 control the flow of the fluid so that the fluid contacts no more than three sides at a given time. Further, it should be noted that the fluid flows in a generally counter clockwise direction when looking at FIG. 4A around the conductor 20. Further, the rails 74, 76 direct the fluid to make two loops around the conductor 20 without overlapping and without missing any regions of the conductor 20.

The fluid source 28 forces or directs the fluid 24 through the fluid passageway 44 to cool the conductor 20. The design of the fluid source 28 can be varied to suit the cooling requirements of the conductor 20. Referring to FIG. 1, the fluid source 28 illustrated includes (i) a reservoir 86 for receiving the fluid 24, (ii) a heat exchanger 88, i.e. a chiller unit, for cooling the fluid 24, (iv) an outlet pipe 90 which connects the fluid outlet 62 with the heat exchanger 88, (v) a fluid pump 92, and (vi) an inlet pipe 94 for transferring the fluid 24 from the fluid pump 92 to the fluid inlet 60.

The temperature, flow rate, and type of the fluid 24 is selected and controlled by the control system 30 to precisely control the temperature of the conductor 20. For the embodiments illustrated, the fluid temperature is maintained between approximately 20 and 25° C., the flow rate is between approximately one and five liters per minute. A suitable fluid 24 is Flourinert type FC-77, made by 3M Company in Minneapolis, Minn. Preferably, the rate of flow of the fluid 24 and the temperature of fluid 24 is controlled by the control system 30 to maintain an outer surface 96 of the circulation housing 26 at a predetermined temperature. By controlling the temperature of the outer surface 96 of the circulation housing 26, heat transferred from the conductor 20 to the surrounding environment is minimized.

FIGS. 5 and 6 illustrate the actuator 12 used in a stage assembly 100 and the device stage 40, respectively. The stage assembly 100 includes a stage base 102, the device stage 40, a stage mover assembly 106, a support assembly 108, a measurement system 110, and the control system 30.

As illustrated in FIG. 7, the stage assembly 100 is particularly useful for precisely positioning a device or object 112 during a manufacturing and/or an inspection process. The type of object 112 positioned and moved by the stage assembly 100 can be varied. For example, the object 112 can be a semiconductor wafer 114 and the stage assembly 100 can be used as part of an exposure apparatus 116 for precisely positioning the semiconductor wafer 114 during manufacturing of the semiconductor wafer 114. Alternately, for example, the stage assembly 100 can be used to move other types of objects during manufacturing and/or inspection, to move a device under an electron microscope (not shown), or to move a device during a precision measurement operation (not shown).

The stage base 102 supports a portion of the stage assembly 100 above a mounting base 118 (illustrated in FIG. 7). The device stage 40 retains the device 112. The device stage 40 is precisely moved and supported by the support assembly 108 to precisely position the device 112. In the embodiment illustrated in the Figures, the device stage 40 includes a device holder (not shown), a portion of the support assembly 108 and a portion of the measurement system 110. The device holder retains the device 112 during movement. The device holder can be a vacuum chuck, an electrostatic chuck, or some other type of clamp. Alternately, the device stage 40 can include multiple device holders for retaining multiple devices 112.

The stage mover assembly 106 cooperates with the support assembly 108 to move and position the device stage 40 relative to the stage base 102. More specifically, in the embodiments illustrated herein, the stage mover assembly 106 follows the device stage 40 and carries a portion of the support assembly 108 so that the support assembly 108 can position and support the device stage 40.

In the embodiment illustrated in the Figures, the stage mover assembly 106 includes (i) the mover housing 42, (ii) a guide assembly 120, (iii) a left X guide mover 122, (iv) a right X guide mover 124, (v) a Y guide mover 126, and (vi) a Y housing mover 128.

Referring to FIG. 6, the mover housing 42 is somewhat rectangular tube and includes a guide opening that is sized and shaped to receive a portion of the guide assembly 120. In the embodiments provided herein, the mover housing 42 is maintained above the stage base 102 with a vacuum preload type fluid bearing. Further, the mover housing 42 is maintained apart from the guide assembly 120 with a fluid bearing.

The guide assembly 120 guides the movement of the mover housing 42 along the Y axis. In the embodiment illustrated in FIG. 5, the guide assembly 120 is generally rectangular shaped and includes a left end and a right end. The guide assembly 120 also includes a pair of spaced apart, guide fluid pads 130. In this embodiment, the guide fluid pads 130 and the guide assembly 120 is supported above the stage base 102 with a vacuum preload type, fluid bearing.

The guide movers 122, 124, 126 and the Y housing mover 128 move the guide assembly 120 and the mover housing 42 relative to the stage base 102. In the embodiment illustrated in FIG. 5, (i) the X guide movers 122, 124 move the guide assembly 120 and mover housing 42 with a relatively large displacement along the X axis and with a limited range of motion about the Z axis (theta Z), (ii) the Y guide mover 126 moves the guide assembly 120 with a small displacement along the Y axis, and (iii) the Y housing mover 128 moves the mover housing 42 with a relatively large displacement along the Y axis.

In the embodiments provided herein, the Y guide mover 126 includes an actuator combination 11 as described above. In this embodiment, the I shaped core 22 is secured to a left mover mount 132 while the opposed electromagnets 14 are secured to the guide assembly 120. Further, in the embodiments provided herein, the X guide movers 122, 124 and the Y housing mover 128 are commutated, linear motors.

The support assembly 108 supports and positions the device stage 104 relative to the mover housing 42 and the stage base 102. For example, the support assembly 108 can adjust the position of the device stage 40 relative to the mover housing 42 with six degrees of freedom. Alternately, for example, the support assembly 108 can be designed to move the device stage 40 relative to the mover housing 42 with only three degrees of freedom.

In the design illustrated in FIG. 6, the support assembly 108 moves and supports the device stage 40 with six degrees of freedom. In this embodiment, the support assembly 108 includes (i) three spaced apart Z stage movers 134 (ii) a pair of spaced apart X stage movers 136, and (iii) a Y stage mover 138. The stage movers 134, 136, 138 cooperate to move and position the device stage 40 (i) along the X axis, Y axis and Z axis, and (ii) about the X axis, Y axis and Z axis relative to the mover housing 42 and the stage base 102.

More specifically, the Z stage movers 134 cooperate to selectively move and support the device stage 40 along the Z axis, about the X axis and about the Y axis. The X stage movers 136 cooperate to move the device stage 40 along the X axis and about the Z axis. The Y stage mover 138 moves the device stage 40 along the Y axis. In the embodiment illustrated in FIG. 6, each of the Z stage movers 134 is commonly referred to as a voice coil motor, each of the X stage movers 136 is an actuator combination 11 as described above and the Y stage mover 138 is an actuator combination 11 as described above. More specifically, the targets 16 are fixed to the device stage 40 and opposing pairs of the electromagnets 14 are secured to a mover housing 42 on opposite sides of each of the targets 16. By directing a current through the one conductor 20 of the pair of electromagnets 14 larger than the current through the other conductor 20 in the pair of electromagnets 14, a differential force can be produced that draws the target 16 in one direction or its opposing direction. Alternately, each of the Z stage movers could be an actuator combination as provided herein.

The measurement system 110 monitors movement of the device stage 40 relative to the stage base 102, or to some other reference such as an optical assembly 200 (illustrated in FIG. 7). With this information, the support assembly 108 precisely positions of the device stage 40. The design of the measurement system 110 can be varied. For example, the measurement system 110 can utilize laser interferometers, encoders, and/or other measuring devices to monitor the position of the device stage 40.

Typically, the measurement system 110 monitors the position of the device stage 40 (i) along a X axis, a Y axis, and a Z axis and (ii) about the X axis, the Y axis and the Z axis relative to the optical assembly 200.

In the embodiment illustrated in FIGS. 5 and 7, the measurement system 20 includes an X sensor 140, a Y sensor 142, and a Z sensor 144. The X sensor 140 is an interferometer that includes an XZ mirror 146 and an X block 148. The X block 148 interacts with the XZ mirror 146 to monitor the location of the device stage 40 along the X axis and about the Z axis (theta Z). More specifically, the X block 148 generates a pair of spaced apart laser beams (not shown) and detects the beams that are reflected off of the XZ mirror 146. With this information, the location of the device stage 40 along the X axis and about the Z axis can be monitored. In the embodiment illustrated in the Figures, the XZ mirror 146 is rectangular shaped and extends along one side of the device stage 40. The X block 148 is positioned away from the mover housing 42.

Somewhat similarly, the Y sensor 142 is an interferometer that includes a YZ mirror 150 and a Y block 152. The YZ mirror 150 interacts with the Y block 152 to monitor the position of the device stage 40 along the Y axis. More specifically, the Y block 152 generates a laser beam and detects the beams that are reflected off of the YZ mirror 150. With this information, the location of the device stage 40 along the Y axis can be monitored. In the embodiment illustrated in the Figures, the YZ mirror 150 is rectangular shaped and is positioned along one of the sides of the device stage 40. The Y block 152 is positioned away from the device stage 40.

The Z sensor 144 is an interferometer that includes a first Z block 154 and a second Z block 156. The Z blocks 154, 156 interact with the XZ mirror 146 and the YZ mirror 150 to monitor the position of the device stage 40 relative to the lens assembly 200 along the Z axis, about the X axis, and about the Y axis. More specifically, the Z blocks 154, 156 generate three laser beams and detect the beams that are reflected off of the mirrors 146, 150. With this information, the location of the device stage 40 along the Z axis, about the X axis, and about the Y axis can be monitored. The Z blocks 154, 156 are connected to optical assembly 200.

The control system 30 also controls the stage mover assembly 106 and the support assembly 108 to precisely position the device stage 40 and the device 112. In the embodiment illustrated herein, the control system 30 directs and controls the current to each of the X guide movers 122, 124 to control movement of the guide assembly 120 along the X axis and about the Z axis. Similarly, the control system 30 directs and controls the current to the Y housing mover 128 to control the position of the mover housing 42 along the guide assembly 120 and the conductors 20 of the Y guide mover 126 to control movement of the guide assembly 120 along the Y axis. Additionally, the control system 30 controls the stage movers 134, 136, 138 in the support assembly 108 to control the position of the device stage 40 with six degrees of freedom.

Importantly, with the present invention, the circulating system 10 maintains the outer surface 96 of each actuator 12 at a set temperature. This minimizes the effect of the actuators 12 on the temperature of the surrounding environment. This also allows the measurement system 110 to take accurate measurements of the position of the device stage 40. As a result thereof, the quality of the integrated circuits formed on the wafer 114 is improved.

FIG. 7 is a schematic view illustrating the exposure apparatus 116 useful with the present invention. The exposure apparatus 116 includes the apparatus frame 202, an illumination system 204 (irradiation apparatus), a reticle stage assembly 206, the optical assembly 200 (lens assembly), and a wafer stage assembly 210. The actuators 12 provided herein can be used in the reticle stage assembly 206 and the wafer stage assembly 210.

The exposure apparatus 116 is particularly useful as a lithographic device that transfers a pattern (not shown) of an integrated circuit from a reticle 211 onto the semiconductor wafer 114. The exposure apparatus 116 mounts to the mounting base 118, e.g., the ground, a base, or floor or some other supporting structure.

The apparatus frame 202 is rigid and supports the components of the exposure apparatus 116. The design of the apparatus frame 202 can be varied to suit the design requirements for the rest of the exposure apparatus 116. The apparatus frame 202 illustrated in FIG. 7 supports the optical assembly 200 and the illumination system 204 and the reticle stage assembly 206 above the mounting base 118.

The illumination system 204 includes an illumination source 212 and an illumination optical assembly 214. The illumination source 212 emits a beam (irradiation) of light energy. The illumination optical assembly 214 guides the beam of light energy from the illumination source 212 to the optical assembly 200. The beam illuminates selectively different portions of the reticle and exposes the semiconductor wafer. In FIG. 7, the illumination source 212 is illustrated as being supported above the reticle stage assembly 206. Typically, however, the illumination source 212 is secured to one of the sides of the apparatus frame 202 and the energy beam from the illumination source 212 is directed to above the reticle stage assembly 206 with the illumination optical assembly 214.

The optical assembly 200 projects and/or focuses the light passing through the reticle to the wafer. Depending upon the design of the exposure apparatus 30, the optical assembly 200 can magnify or reduce the image illuminated on the reticle.

The reticle stage assembly 206 holds and positions the reticle relative to the optical assembly 200 and the wafer. Similarly, the wafer stage assembly 210 holds and positions the wafer with respect to the projected image of the illuminated portions of the reticle in the operational area. In FIG. 7, the wafer stage assembly 210 utilizes actuators 12 having features of the present invention. Depending upon the design, the exposure apparatus 116 can also include additional actuators to move the stage assemblies 206, 210.

There are a number of different types of lithographic devices. For example, the exposure apparatus 116 can be used as scanning type photolithography system that exposes the pattern from the reticle onto the wafer with the reticle and the wafer moving synchronously. In a scanning type lithographic device, the reticle is moved perpendicular to an optical axis of the optical assembly 200 by the reticle stage assembly 206 and the wafer is moved perpendicular to an optical axis of the optical assembly 200 by the wafer stage assembly 210. Scanning of the reticle and the wafer occurs while the reticle and the wafer are moving synchronously.

Alternately, the exposure apparatus 116 can be a step-and-repeat type photolithography system that exposes the reticle while the reticle and the wafer are stationary. In the step and repeat process, the wafer is in a constant position relative to the reticle and the optical assembly 200 during the exposure of an individual field. Subsequently, between consecutive exposure steps, the wafer is consecutively moved by the wafer stage perpendicular to the optical axis of the optical assembly 200 so that the next field of the wafer is brought into position relative to the optical assembly 200 and the reticle for exposure. Following this process, the images on the reticle are sequentially exposed onto the fields of the wafer so that the next field of the wafer is brought into position relative to the optical assembly 200 and the reticle.

However, the use of the exposure apparatus 116 provided herein is not limited to a photolithography system for semiconductor manufacturing. The exposure apparatus 116, for example, can be used as an LCD photolithography system that exposes a liquid crystal display device pattern onto a rectangular glass plate or a photolithography system for manufacturing a thin film magnetic head. Further, the present invention can also be applied to a proximity photolithography system that exposes a mask pattern by closely locating a mask and a substrate without the use of a lens assembly. Additionally, the actuator combination 11 provided herein can be used in other devices, including other semiconductor processing equipment, elevators, electric razors, machine tools, metal cutting machines, inspection machines and disk drives.

The illumination source 212 can be g-line (436 nm), i-line (365 nm), KrF excimer laser (248 nm), ArF excimer laser (193 nm) and F₂ laser (157 nm). Alternately, the illumination source 212 can also use charged particle beams such as an x-ray and electron beam. For instance, in the case where an electron beam is used, thermionic emission type lanthanum hexaboride (LaB₆) or tantalum (Ta) can be used as an electron gun. Furthermore, in the case where an electron beam is used, the structure could be such that either a mask is used or a pattern can be directly formed on a substrate without the use of a mask.

In terms of the magnification of the optical assembly 200 included in the photolithography system, the optical assembly 200 need not be limited to a reduction system. It could also be a 1× or magnification system.

With respect to a optical assembly 200, when far ultra-violet rays such as the excimer laser is used, glass materials such as quartz and fluorite that transmit far ultra-violet rays is preferable to be used. When the F₂ type laser or x-ray is used, the optical assembly 200 should preferably be either catadioptric or refractive (a reticle should also preferably be a reflective type), and when an electron beam is used, electron optics should preferably consist of electron lenses and deflectors. The optical path for the electron beams should be in a vacuum.

Also, with an exposure device that employs vacuum ultra-violet radiation (VUV) of wavelength 200 nm or lower, use of the catadioptric type optical system can be considered. Examples of the catadioptric type of optical system include the disclosure Japan Patent Application Disclosure No.8-171054 published in the Official Gazette for Laid-Open Patent Applications and its counterpart U.S. Pat. No. 5,668,672, as well as Japan Patent Application Disclosure No.10-20195 and its counterpart U.S. Pat. No. 5,835,275. In these cases, the reflecting optical device can be a catadioptric optical system incorporating a beam splitter and concave mirror. Japan Patent Application Disclosure No.8-334695 published in the Official Gazette for Laid-Open Patent Applications and its counterpart U.S. Pat. No. 5,689,377 as well as Japan Patent Application Disclosure No.10-3039 and its counterpart U.S. patent application Ser. No. 873,605 (Application Date: Jun. 12, 1997) also use a reflecting-refracting type of optical system incorporating a concave mirror, etc., but without a beam splitter, and can also be employed with this invention. As far as is permitted, the disclosures in the above-mentioned U.S. patents, as well as the Japan patent applications published in the Official Gazette for Laid-Open Patent Applications are incorporated herein by reference.

Further, in photolithography systems, when linear motors (see U.S. Pat. Nos. 5,623,853 or 5,528,100) are used in a wafer stage or a mask stage, the linear motors can be either an air levitation type employing air bearings or a magnetic levitation type using Lorentz force or reactance force. Additionally, the stage could move along a guide, or it could be a guideless type stage that uses no guide. As far as is permitted, the disclosures in U.S. Pat. Nos. 5,623,853 and 5,528,100 are incorporated herein by reference.

Alternatively, one of the stages could be driven by a planar motor, which drives the stage by an electromagnetic force generated by a magnet unit having two-dimensionally arranged magnets and an armature coil unit having two-dimensionally arranged coils in facing positions. With this type of driving system, either the magnet unit or the armature coil unit is connected to the stage and the other unit is mounted on the moving plane side of the stage.

Movement of the stages as described above generates reaction forces that can affect performance of the photolithography system. Reaction forces generated by the wafer (substrate) stage motion can be mechanically released to the floor (ground) by use of a frame member as described in U.S. Pat. No. 5,528,100 and published Japanese Patent Application Disclosure No. 8-136475. Additionally, reaction forces generated by the reticle (mask) stage motion can be mechanically released to the floor (ground) by use of a frame member as described in U.S. Pat. No. 5,874,820 and published Japanese Patent Application Disclosure No. 8-330224. As far as is permitted, the disclosures in U.S. Pat. Nos. 5,528,100 and 5,874,820 and Japanese Patent Application Disclosure No. 8-330224 are incorporated herein by reference.

As described above, a photolithography system (an exposure apparatus) according to the above described embodiments can be built by assembling various subsystems, including each element listed in the appended claims, in such a manner that prescribed mechanical accuracy, electrical accuracy, and optical accuracy are maintained. In order to maintain the various accuracies, prior to and following assembly, every optical system is adjusted to achieve its optical accuracy. Similarly, every mechanical system and every electrical system are adjusted to achieve their respective mechanical and electrical accuracies. The process of assembling each subsystem into a photolithography system includes mechanical interfaces, electrical circuit wiring connections and air pressure plumbing connections between each subsystem. Needless to say, there is also a process where each subsystem is assembled prior to assembling a photolithography system from the various subsystems. Once a photolithography system is assembled using the various subsystems, a total adjustment is performed to make sure that accuracy is maintained in the complete photolithography system. Additionally, it is desirable to manufacture an exposure system in a clean room where the temperature and cleanliness are controlled.

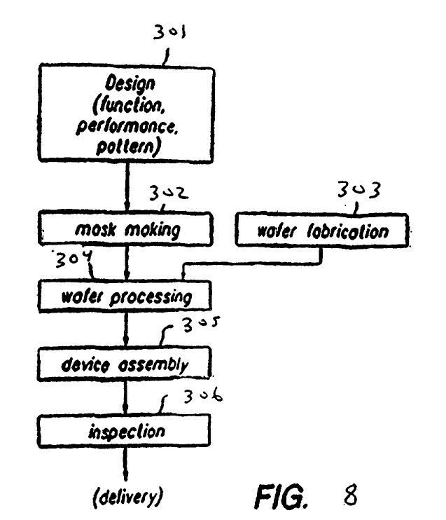

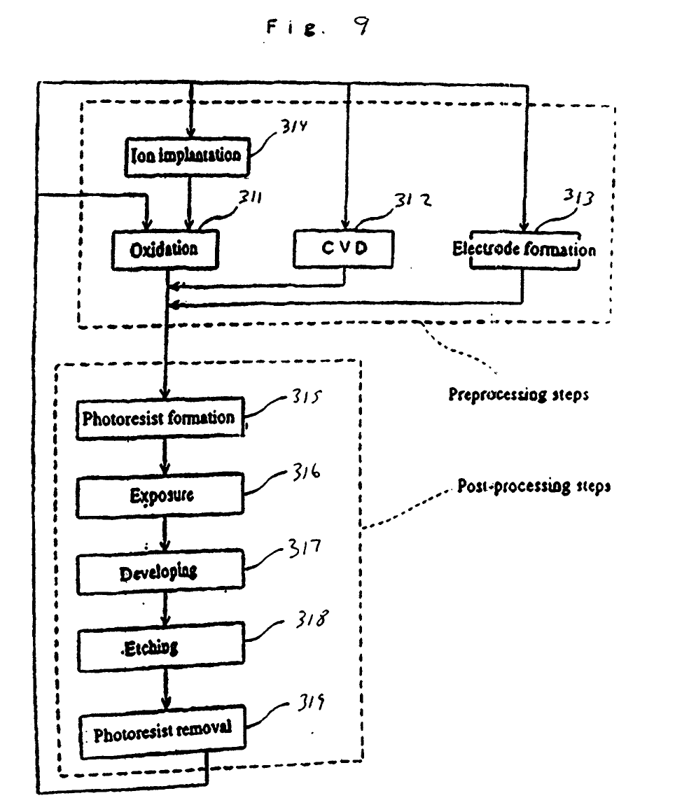

Further, semiconductor devices can be fabricated using the above described systems, by the process shown generally in FIG. 8. In step 301 the device's function and performance characteristics are designed. Next, in step 302, a mask (reticle) having a pattern is designed according to the previous designing step, and in a parallel step 303 a wafer is made from a silicon material. The mask pattern designed in step 302 is exposed onto the wafer from step 303 in step 304 by a photolithography system described hereinabove in accordance with the present invention. In step 305 the semiconductor device is assembled (including the dicing process, bonding process and packaging process), finally, the device is then inspected in step 306.

FIG. 9 illustrates a detailed flowchart example of the above-mentioned step 304 in the case of fabricating semiconductor devices. In FIG. 9, in step 311 (oxidation step), the wafer surface is oxidized. In step 312 (CVD step), an insulation film is formed on the wafer surface. In step 313 (electrode formation step), electrodes are formed on the wafer by vapor deposition. In step 314 (ion implantation step), ions are implanted in the wafer. The above mentioned steps 311-314 form the preprocessing steps for wafers during wafer processing, and selection is made at each step according to processing requirements.

At each stage of wafer processing, when the above-mentioned preprocessing steps have been completed, the following post-processing steps are implemented. During post-processing, first, in step 315 (photoresist formation step), photoresist is applied to a wafer. Next, in step 316 (exposure step), the above-mentioned exposure device is used to transfer the circuit pattern of a mask (reticle) to a wafer. Then in step 317 (developing step), the exposed wafer is developed, and in step 318 (etching step), parts other than residual photoresist (exposed material surface) are removed by etching. In step 319 (photoresist removal step), unnecessary photoresist remaining after etching is removed.

Multiple circuit patterns are formed by repetition of these preprocessing and post-processing steps.

While the particular actuator 12 and circulating system 10 as herein shown and disclosed in detail is fully capable of obtaining the objects and providing the advantages herein before stated, it is to be understood that it is merely illustrative of the presently preferred embodiments of the invention and that no limitations are intended to the details of construction or design herein shown other than as described in the appended claims.

What is claimed is:

1. A circulating system for circulating a fluid from a fluid source near a substantially tubular shaped conductor, the circulating system comprising:
a circulation housing that is sized and shaped to substantially encircle the conductor and provide a fluid passageway between the circulation housing and the conductor; and
a fluid inlet into the fluid passageway, the fluid inlet being in fluid communication with the fluid source so that fluid from the fluid source is supplied to the fluid passageway.

2. The circulating system of claim 1 including a fluid guide that extends between the circulation housing and the conductor, the fluid guide supporting the conductor spaced apart from the circulation housing.

3. The circulating system of claim 1 including a fluid guide that guides the flow of the fluid in the fluid passageway so that the fluid flows around the conductor.

4. The circulating system of claim 3 wherein the fluid guide includes a first rail that is positioned in the fluid passageway, the first rail directing the flow of fluid in the fluid passageway.

5. The circulating system of claim 3 wherein the fluid guide includes a first rail and a second rail that are positioned in the fluid passageway, the rails cooperating to direct the flow of fluid in the fluid passageway over an outer perimeter, a top surface, a bottom surface and an inner perimeter of the conductor.

6. The circulating system of claim 5 wherein the fluid inlet is positioned to direct the fluid between the rails in the fluid passageway.

7. The circulating system of claim 1 wherein the circulation housing includes a housing outer shell that encircles the conductor.

8. The circulating system of claim 7 wherein the circulation housing includes a housing inner shell that is sized and shaped to be substantially encircled by the conductor.

9. The circulating system of claim 8 wherein the housing outer shell and the housing inner shell are substantially coaxial.

10. The circulating system of claim 1 wherein the fluid is used for cooling the conductor.

11. An actuator combination including a first core, a second core, a conductor, and the circulating system of claim 1.

12. The actuator combination of claim 11 wherein the first core is E shaped and the second core is I shaped.

13. A stage assembly including the actuator combination of claim 11.

14. An exposure apparatus including the actuator combination of claim 11.

15. An object on which an image has been formed by the exposure apparatus of claim 14.

16. A semiconductor wafer on which an image has been formed by the exposure apparatus of claim 14.

17. An actuator combination for use with a fluid source including a fluid, the actuator combination comprising:
a first core;
a substantially tubular shaped conductor; and
a circulating system that circulates the fluid, the circulating system including (i) a circulation housing having a tubular shaped, housing cavity which receives the conductor and provides a fluid passageway between the circulation housing and the conductor, and (ii) a fluid inlet into the fluid passageway, the fluid inlet being in fluid communication with the fluid source so that fluid from the fluid source can be supplied to the fluid passageway.

18. The actuator combination of claim 17 including a fluid guide that extends between the circulation housing and the conductor, the fluid guide supporting the conductor spaced apart from the circulation housing.

19. The actuator combination of claim 17 including a fluid guide that guides the flow of the fluid in the fluid passageway so that the fluid flows around the conductor.

20. The actuator combination of claim 17 wherein the fluid guide includes a first rail and a second rail that are positioned in the fluid passageway, the rails cooperating to direct the flow of fluid in the fluid passageway over an outer perimeter, a top surface, a bottom surface and an inner perimeter of the conductor.

21. The actuator combination of claim 17 wherein the circulation housing includes a housing outer shell that encircles the conductor, and a housing inner shell that is sized and shaped to be substantially encircled by the conductor, wherein the outer shell and the inner shell are substantially coaxial.

22. The actuator combination wherein the first core is E shaped and the conductor substantially encircles a portion of the first core.

23. A stage assembly including the actuator combination of claim 17.

24. An exposure apparatus including the actuator combination of claim 17.

25. An object on which an image has been formed by the exposure apparatus of claim 24.

26. A semiconductor wafer on which an image has been formed by the exposure apparatus of claim 24.

27. A method for cooling a substantially tubular shaped conductor, the method comprising the steps of:
providing a circulation housing including a tubular shaped housing cavity that receives the conductor and defines a fluid passageway between the circulation housing and the conductor;
positioning the conductor in the housing cavity; and
directing a fluid through the fluid passageway to cool the conductor.

28. The method of claim 27 including the step of positioning a fluid guide between the conductor and the circulation housing, the fluid guide maintaining the conductor spaced apart from the circulation housing.

29. The method of claim 27 including the step of guiding the flow of fluid in the fluid passageway around the conductor with a fluid guide.

30. The method of claim 27 including the step of controlling the rate of flow of the fluid so that an outer surface of the circulation housing is maintained at a set temperature.

31. A method for making a circulating system adapted for use with a fluid from a fluid source for an attraction only type actuator including a conductor, the method comprising the steps of:
providing a circulation housing that is sized and shaped to substantially encircle the conductor and provide a fluid passageway between the circulation housing and the conductor; and
providing a fluid inlet into the fluid passageway in fluid communication with the fluid source so that the fluid from the fluid source can be supplied to the fluid passageway.

32. A method for making an exposure apparatus that forms an image on an object, the method comprising the steps of:
providing an irradiation apparatus that irradiates the object with radiation to form the image on the object;
providing an actuator as a driving force for moving the object; and
connecting the circulating system made by the method of claim 31 to the actuator.

33. A method of making an object utilizing the exposure apparatus made by the method of claim 32.

34. A method for making an actuator combination adapted for use with a fluid source including a fluid, the method comprising the steps of:
providing a first core;
providing a substantially tubular shaped conductor that encircles a portion of the first core; and
providing a circulating system including (i) a circulation housing that encircles the conductor and provides a fluid passageway between the circulation housing and the conductor, and (ii) a fluid inlet into the fluid passageway in fluid communication with the fluid source so that the fluid from the fluid source can be supplied to the fluid passageway.

35. A method for making an exposure apparatus that forms an image on an object, the method comprising the steps of:
providing an irradiation apparatus that irradiates the object with radiation to form the image on the object; and
providing an actuator combination made by the method of claim 34.

36. A method of making an object utilizing the exposure apparatus made by the method of claim 35.
